(19) United States
(12) Patent Application Publication
(10) Pub. No.: US 2025/0268078 A1
(43) Pub. Date: Aug. 21, 2025

(54) DISPLAY DEVICE AND ELECTRICAL DEVICE INCLUDING THE DISPLAY DEVICE

(71) Applicant: Samsung Display Co., LTD., Yongin-si (KR)

(72) Inventors: JONGHO SON, Yongin-si (KR); OHJEONG KWON, Yongin-si (KR); DAEWON KIM, Yongin-si (KR); TAEHO KIM, Yongin-si (KR); MIHWA LEE, Yongin-si (KR); SUNGGYU JANG, Yongin-si (KR)

(21) Appl. No.: 18/978,467

(22) Filed: Dec. 12, 2024

(30) Foreign Application Priority Data
Feb. 20, 2024 (KR) 10-2024-0024641

(51) Int. Cl. H10K 59/80; H10H 29/85; H10H 29/855; H10K 59/38

(52) U.S. Cl. CPC H10K 59/879; H10H 29/8517; H10H 29/855; H10K 59/38; H10K 59/8793

(57) ABSTRACT

A display device includes a display panel in which a plurality of pixels are arranged side by side, a micro lens array disposed on the display panel and refracting light emitted from each pixel according to a chief ray angle defined for each pixel, and a window disposed on the micro lens array.

This application claims priority to Korean Patent Application No. 10-2024-0024641, filed on Feb. 20, 2024, and all the benefits accruing therefrom under 35 U.S.C. § 119, the content of which in its entirety is herein incorporated by reference.

### BACKGROUND

### Field

Embodiments supported by aspects of the present disclosure relate generally to a display device and an electrical device including the display device.

### Description of the Related Art

A light emitting diode (LED) is an element that may convert electrical signals into light forms such as, for example, infrared and visible light by using the characteristics of compound semiconductors. In particular, a light emitting diode is a semiconductor element that converts energy generated by recombination of holes and electrons into light energy in which, when a voltage is applied to the P-N diode in the forward direction, holes and electrons are injected.

### SUMMARY

Embodiments provide a display device.

Embodiments provide an electrical device including the display device.

A display device according to an embodiment includes a display panel in which a plurality of pixels are arranged side by side, a micro lens array disposed on the display panel and configured to refract light emitted from each of the pixels according to a chief ray angle defined for each of the pixels, and a window disposed on the micro lens array.

In an embodiment, the micro lens array may include Fresnel lenses disposed on the pixels.

In an embodiment, each of the Fresnel lenses may have a concave shape.

In an embodiment, lens angles of the Fresnel lenses may increase from a center to an outside of the display panel.

In an embodiment, each of the lens angles may be greater than a corresponding chief ray angle.

In an embodiment, chief ray angles of the pixels may increase from a center to an outside of the display panel.

In an embodiment, the micro lens array may be configured to refract the emitted light and reflected light associated with the emitted light according to the chief ray angle.

In an embodiment, the display device may further include a polarizing layer disposed between the display panel and the micro lens array and configured to reflect the emitted light.

In an embodiment, the polarizing layer may be a wire grid polarizing layer including grid patterns.

In an embodiment, the display device may further include a phase retardation layer disposed between the display panel and the micro lens array and configured to delay a phase of the emitted light.

In an embodiment, each of the pixels may include a pixel electrode and a color filter disposed on the pixel electrode, and a horizontal separation distance between a center of a pixel electrode included in a first pixel for which a first chief ray angle is defined and a center of a color filter included in the first pixel may be substantially equal to a horizontal separation distance between a center of a pixel electrode included in a second pixel for which a second chief ray angle, which is smaller than the first chief ray angle, is defined and a center of a color filter included in the second pixel.

In an embodiment, the first pixel may be located closer to an outside of the display panel than the second pixel.

In an embodiment, each of the pixels may include an intermediate layer in which at least two emission layers are stacked.

In an embodiment, the intermediate layer may emit white light.

In an embodiment, the display panel may include a substrate, and the substrate may be a silicon wafer including silicon or a sapphire substrate including sapphire.

In an embodiment, the display device may further include a planarization layer disposed between the micro lens array and the window.

An electrical device according to an embodiment includes a display device and an optical member disposed in a path of light emitted from the display device and including at least one lens part. The display device includes a display panel in which a plurality of pixels are arranged side by side, a micro lens array disposed on the display panel and configured to refract light emitted from each of the pixels according to a chief ray angle defined for each of the pixels, and a window disposed on the micro lens array.

In an embodiment, the lens part may include a lens and a phase retardation layer disposed adjacent to the lens.

Therefore, a display device according to embodiments of the present invention may include a micro lens array, and the micro lens array may refract emitted light and reflected light according to a chief ray angle. For example, the micro lens array may include first to third Fresnel lenses respectively corresponding to first to third pixels. Lens angles of the first to third Fresnel lenses may be set to correspond to the first to third chief ray angles defined for each of the first to third pixels.

As the display device includes the micro lens array, front light having a relatively large amount of light and relatively high recycling efficiency may be refracted according to the chief ray angle. Accordingly, light extraction efficiency for pixels located on the outside of the display panel may be improved.

In some aspects, as the display device includes the micro lens array, the horizontal separation distance between the pixel electrode, the color filter, and the lens may not be shift aligned. Accordingly, the economic efficiency of the process of manufacturing the display device DD may be improved.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a diagram illustrating an electrical device according to an embodiment of the present invention.

FIG. 2 is a cross-sectional view illustrating a display device included in the electrical device of FIG. 1.

FIGS. 3, 4, and 5 are cross-sectional views illustrating various examples of an intermediate layer included in the display device of FIG. 2.

FIG. 6 is an enlarged view of area A of FIG. 2.

FIG. 7 is a graph illustrating a lens angle according to a chief ray angle of a pixel.

FIG. 8 is a diagram illustrating the electrical device of FIG. 1.

FIG. 9 is a perspective view illustrating the electrical device of FIG. 1.

### DETAILED DESCRIPTION

Illustrative, non-limiting embodiments will be more clearly understood from the following detailed description in conjunction with the accompanying drawings.

Embodiments supported by the present disclosure will now be described more fully hereinafter with reference to the accompanying drawings, in which one or more example embodiments are shown. Aspects supported by the present disclosure may, however, be embodied in different forms and should not be construed as limited to the embodiments set forth herein. Rather, these example embodiments are provided such that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually equal (e.g., within a threshold percent of equal). The term “substantially simultaneously” means approximately or actually at the same time (e.g., within a threshold percent of equal). The term “substantially the same” means approximately or actually the same (e.g., within a threshold difference amount).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

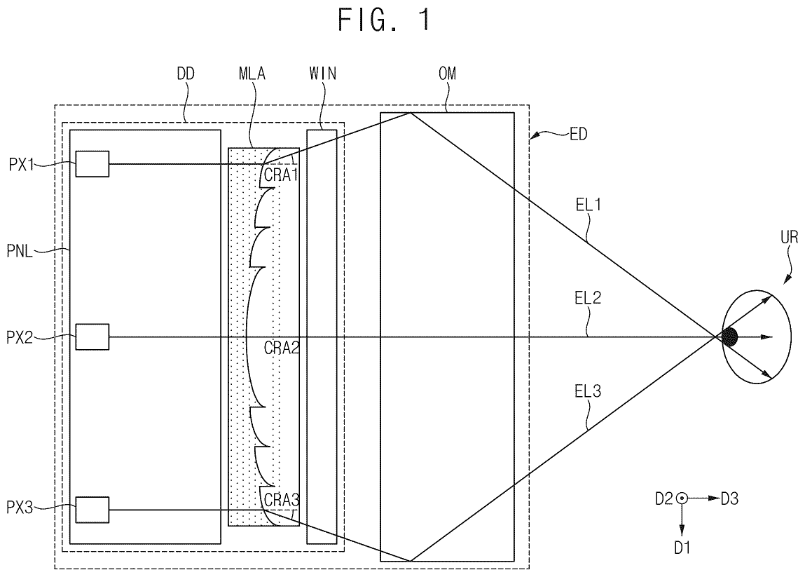

FIG. 1 is a diagram illustrating an electrical device according to an embodiment of the present invention.

Referring to FIG. 1, an electronic device ED according to an embodiment of the present invention may include a display device DD and an optical member OM.

In an embodiment, the display device DD may generate light and may refract and emit the light.

In an embodiment, the display device DD may include a display panel PNL. The display panel PNL may be a miniature light emitting diode display device including a miniature light emitting diode (or micro light emitting diode). However, embodiments of the present disclosure are not limited thereto.

In some aspects, a first pixel PX1, a second pixel PX2, and a third pixel PX3 may be arranged in the display panel PNL. For example, the first to third pixels PX1, PX2, and PX3 may be arranged side by side in a first direction D1.

In this description, the display panel PNL may have a length in the first direction D1 and a thickness in a second direction D2 that intersects the first direction D1. In some aspects, the display panel PNL may emit light in a third direction D3 that intersects the first and second directions D1 and D2.

The first pixel PX1 may be located closer to the outside of the display panel PNL than the second pixel PX2. In some aspects, the third pixel PX3 may be located closer to the outside of the display panel PNL than the second pixel PX2.

The first pixel PX1 may emit first emitted light EL1, and a first chief ray angle CRA1 may be defined in the first pixel PX1. The second pixel PX2 may emit second emitted light EL2, and a second chief ray angle CRA2 may be defined in the second pixel PX2. The third pixel PX3 may emit third emitted light EL3, and a third chief ray angle CRA3 may be defined in the third pixel PX3.

In an embodiment, the first to third emitted light EL1, EL2, and EL3 may be of the same color. In another embodiment, the first to third emitted light EL1, EL2, and EL3 may be of different respective colors.

In an embodiment, the chief ray angles may increase from the center to the outside of the display panel PNL. For example, the first chief ray angle CRA1 (e.g., about 30°) may be greater than the second chief ray angle CRA2 (e.g., about 0°). In some aspects, the third chief ray angle CRA3 (e.g., about) 30° may be greater than the second chief ray angle CRA2.

In an embodiment, the display device DD may include a micro lens array MLA. The micro lens array MLA may refract the light emitted from each pixel according to a chief ray angle defined for each pixel. In detail, the micro lens array MLA may refract the first emitted light EL1 according to the first chief ray angle CRA1, may refract the second emitted light EL2 to according the second chief ray angle CRA2, and may refract the third emitted light EL3 according to the third chief ray angle CRA3.

In an embodiment, the optical member OM may be disposed in a path of light emitted from the display device DD, may refract the light, and may provide the light to a user UR.

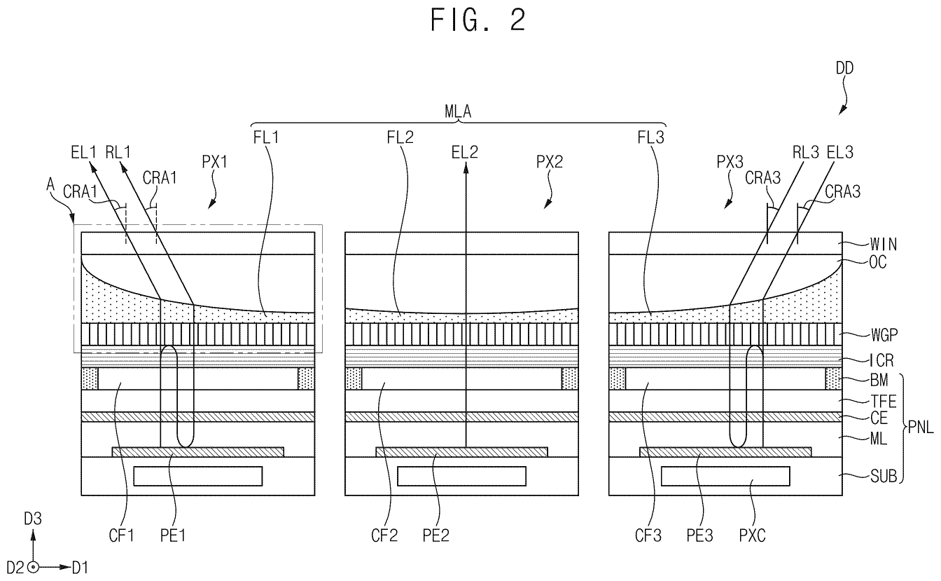

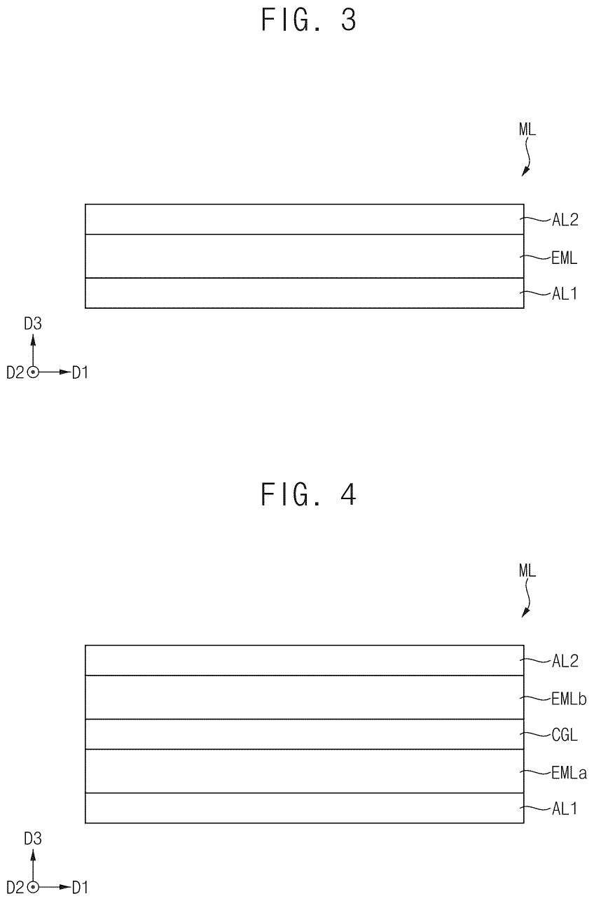

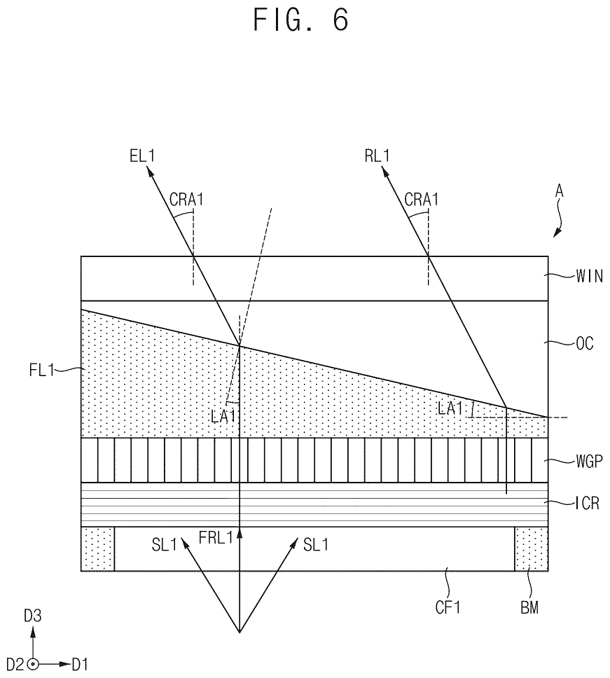

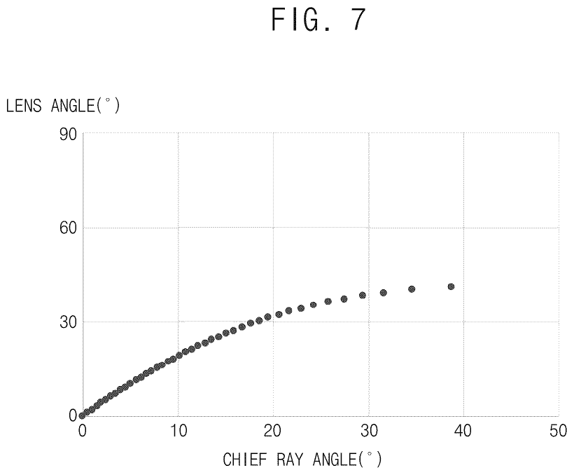

FIG. 2 is a cross-sectional view illustrating a display device included in the electrical device of FIG. 1. FIGS. 3, 4, and 5 are cross-sectional views illustrating various examples of an intermediate layer included in the display device of FIG. 2. FIG. 6 is an enlarged view of area A of FIG. 2. FIG. 7 is a graph illustrating a lens angle according to a chief ray angle of a pixel.

Referring to FIG. 2, the display device DD may include a display panel PNL, a phase retardation layer ICR, a polarizing layer WGP, a micro lens array MLA, a planarization layer OC, and a window WIN.

The display panel PNL may include a substrate SUB, a first pixel electrode PE1, a second pixel electrode PE2, a third pixel electrode PE3, an intermediate layer ML, a common electrode CE, an encapsulation layer TFE, a partition BM, a first color filter CF1, a second color filter CF2, and a third color filter CF3.

The substrate SUB may be a semiconductor circuit board. A pixel circuit PXC may be formed on the substrate SUB. The pixel circuit PXC may include various driving elements, lines, and other components for driving a light emitting diode. For example, the pixel circuit PXC may include a transistor, a capacitor, a gate line, a data line, and the like.

In an embodiment, the substrate SUB may be a silicon wafer substrate including silicon. Alternatively, the substrate SUB may be a sapphire substrate including sapphire. However, embodiments of the present disclosure are not limited thereto, and the substrate SUB may include various materials other than silicon and sapphire.

The first to third pixel electrodes PE1, PE2, and PE3 may be disposed on the substrate SUB. Each of the first to third pixel electrodes PE1, PE2, and PE3 may include metal, alloy metal nitride, conductive metal oxide, or transparent conductive material. Examples of the metal may include silver (Ag), molybdenum (Mo), aluminum (Al), tungsten (W), copper (Cu), nickel (Ni), chromium (Cr), titanium (Ti), and tantalum (Ta), platinum (Pt), scandium (Sc), and the like. Examples of the conductive metal oxide include indium tin oxide and indium zinc oxide. In some aspects, examples of the metal nitride may include aluminum nitride (AlNx), tungsten nitride (WNx), and chromium nitride (CrNx). The described materials can be used individually or in combination with each other.

In an embodiment, each of the first to third pixel electrodes PE1, PE2, and PE3 may be a reflective electrode and may function as an anode electrode.

The intermediate layer ML may be disposed on the first to third pixel electrodes PE1, PE2, and PE3. The intermediate layer ML may continuously extend across the first to third pixels PX1, PX2, and PX3. In an embodiment, the intermediate layer ML may include an emission layer that emits light.

Referring to FIG. 3, the intermediate layer ML may include a first auxiliary layer AL1, an emission layer EML, and a second auxiliary layer AL2.

The first auxiliary layer AL1 may be a charge auxiliary layer for controlling injection and/or mobility of charges. The first auxiliary layer AL1 may have a single-layer structure or a multi-layer structure including a plurality of layers. For example, the first auxiliary layer AL1 may be a hole injection layer, a hole transport layer, an electron blocking layer, an electron injection layer, an electron transport layer, a hole blocking layer, or a combination thereof.

The emission layer EML may be disposed on the first auxiliary layer AL1. The emission layer EML may include an emission material. In an embodiment, the emission layer EML may emit white light. For example, the emission layer EML may include emission materials that emit light of different colors, and the light emitted by the emission materials may be combined to emit white light. The emission material included in the emission layer EML may include an organic light emitting material, an inorganic light emitting material, or a combination thereof.

The second auxiliary layer AL2 may be disposed on the light emission layer EML. The second auxiliary layer AL2 may be a charge auxiliary layer for controlling injection and/or mobility of charges. The second auxiliary layer AL2 may have a single-layer structure or a multi-layer structure including a plurality of layers. For example, the second auxiliary layer AL2 may include a hole injection layer, a hole transport layer, an electron blocking layer, an electron injection layer, an electron transport layer, a hole blocking layer, or a combination thereof.

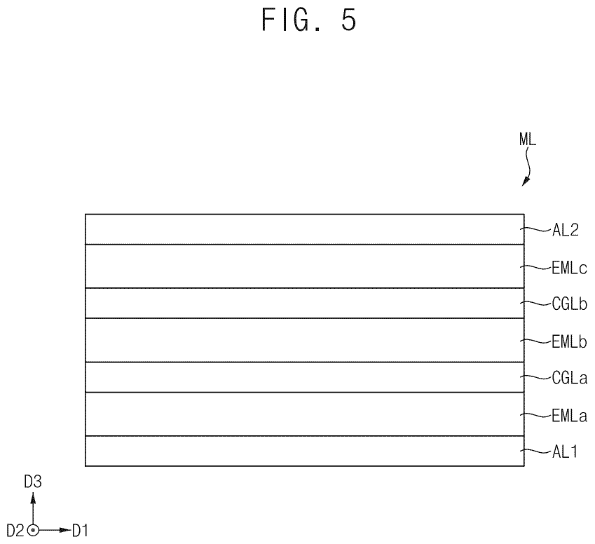

Referring to FIGS. 4 and 5, in an embodiment, the intermediate layer ML may have a structure in which at least two or more emission layers are stacked. That is, the intermediate layer ML may have a tandem structure.

As illustrated in FIG. 4, in an embodiment, the intermediate layer ML may include a first auxiliary layer AL1, a first emission layer EMLa, a charge generation layer CGL, a second emission layer EMLb, and a second auxiliary layer AL2.

The first emission layer EMLa may be disposed on the first auxiliary layer AL1, and the second emission layer EMLb may be disposed on the charge generation layer CGL. The first emission layer EMLa and the second emission layer EMLb may include an emission material. The first emission layer EMLa and the second emission layer EMLb may emit light of the same or different colors. Accordingly, the intermediate layer ML may emit white light. For example, the first emission layer EMLa may emit blue light, and the second emission layer EMLb may emit green light. The emission material included in each of the first emission layer EMLa and the second emission layer EMLb may include an organic light emitting material, an inorganic light emitting material, or a combination thereof.

The charge generation layer CGL may be disposed between the first emission layer EMLa and the second emission layer EMLb. The charge generation layer CGL may inject charges into the first emission layer EMLa and/or the second emission layer EMLb. The charge generation layer CGL may control charge balance between the first emission layer EMLa and the second emission layer EMLb. For example, the charge generation layer CGL may include an n-type semiconductor layer and a p-type semiconductor layer, and the charge generation layer CGL may include an electron transport material and/or a hole transport material containing an n-type dopant and/or a p-type dopant. The charge generation layer CGL may have a single-layer structure or a multi-layer structure in which a plurality of layers are stacked.

As illustrated in FIG. 5, in an embodiment, the intermediate layer ML may include a first auxiliary layer AL1, a first emission layer EMLa, a first charge generation layer CGLa, a second emission layer EMLb, a second charge generation layer CGLb, a third emission layer EMLc, and a second auxiliary layer AL2.

The first emission layer EMLa may be disposed on the first auxiliary layer AL1, the second emission layer EMLb may be disposed between the first charge generation layer CGLa and the second charge generation layer CGLb, and the third emission layer EMLc may be disposed on the second charge generation layer CGLc.

The first emission layer EMLa, the second emission layer EMLb, and the third emission layer EMLc may include an emission material. The first emission layer EMLa, the second emission layer EMLb, and the third emission layer EMLc may emit light of the same or different colors. Accordingly, the intermediate layer ML may emit white light. For example, the first emission layer EMLa and the third emission layer EMLc may emit blue light, and the second emission layer EMLb may emit green light. The emission material included in each of the first emission layer EMLa, the second emission layer EMLb, and the third emission layer EMLc may include an organic light emitting material, an inorganic light emitting material, or a combination thereof.

The first charge generation layer CGLa may be disposed between the first emission layer EMLa and the second emission layer EMLb. The first charge generation layer CGLa may inject charges into the first emission layer EMLa and/or the second emission layer EMLb. The first charge generation layer CGLa may control charge balance between the first emission layer EMLa and the second emission layer EMLb. For example, the first charge generation layer CGLa may include an n-type semiconductor layer and a p-type semiconductor layer, and the first charge generation layer CGLa may include an electron transport material and/or a hole transport material containing an n-type dopant and/or a p-type dopant. The first charge generation layer CGLa may have a single-layer structure or a multi-layer structure in which a plurality of layers are stacked.

The second charge generation layer CGLb may be disposed between the second emission layer EMLb and the third emission layer EMLc. The second charge generation layer CGLb may inject charges into the second emission layer EMLb and/or the third emission layer EMLc. The second charge generation layer CGLb may control charge balance between the second emission layer EMLb and the third emission layer EMLc. For example, the second charge generation layer CGLb may include an n-type semiconductor layer and a p-type semiconductor layer, and the second charge generation layer CGLb may include an electron transport material and/or a hole transport material containing an n-type dopant and/or a p-type dopant. The second charge generation layer CGLb may have a single-layer structure or a multi-layer structure in which a plurality of layers are stacked.

Referring again to FIG. 2, the common electrode CE may be disposed on the intermediate layer ML. The common electrode CE may continuously extend across the first to third pixels PX1, PX2, and PX3. The common electrode CE may include metal, alloy metal nitride, conductive metal oxide, transparent conductive material, or the like.

In an embodiment, the common electrode CE may be a transmissive electrode or a semi-transmissive electrode and may function as a cathode electrode.

The encapsulation layer TFE may be disposed on the common electrode CE. In an embodiment, the encapsulation layer TFE may include at least one inorganic layer and at least one organic layer. The encapsulation layer TFE may prevent foreign substances from penetrating into the intermediate layer ML.

The partition BM may be disposed on the encapsulation layer TFE. The partition BM may define areas of the first to third pixels PX1, PX2, and PX3.

The partition BM may include a light blocking material. In an embodiment, examples of the light blocking material that can be used as the partition BM may include organic materials and/or inorganic materials containing black pigment, black dye, or the like. In another embodiment, the partition BM may include a reflective material such as, for example, a metal material. Accordingly, the partition BM may prevent color mixing between the first to third pixels PX1, PX2, and PX3.

The first color filter CF1 may overlap the first pixel electrode PE1, the second color filter CF2 may overlap the second pixel electrode PE2, and the third color filter CF3 may overlap the third pixel electrode PE3. Each of the first to third color filters CF1, CF2, and CF3 may selectively transmit light of a specific wavelength and absorb light of the remaining wavelengths.

The phase retardation layer ICR may be disposed on the first to third color filters CF1, CF2, and CF3. The phase retardation layer ICR may delay the phase of light.

In an embodiment, the phase retardation layer ICR may include an alignment layer and a reactive liquid crystal monomer. The reactive liquid crystal monomer may be arranged along the alignment direction formed on the alignment layer. The alignment layer may include an alignment material such as, for example, polyimide, polyamide, azobenzene, or cinnamate. The reactive liquid crystal monomer may include a polymer of reactive mesogen that exhibits liquid crystallinity.

The polarizing layer WGP may be disposed on the phase retardation layer ICR. In an embodiment, the polarizing layer WGP may be a reflective polarizing layer. For example, the polarizing layer WGP may include a plurality of grid patterns. The grid patterns may be spaced apart from each other at predetermined intervals. In some aspects, the grid patterns may include a metal material with a relatively high reflectivity. For example, examples of the metal material that can be used as the polarizing layer WGP may include aluminum (Al), gold (Au), silver (Ag), copper (Cu), chromium (Cr), iron (Fe), nickel (Ni), or the like. The described materials can be used alone or in combination with each other. In other words, the polarizing layer WGP may be a wire grid polarizing layer. In another embodiment, the polarizing layer WGP may be an absorption-type polarizing layer.

In an example in which the polarizing layer WGP is a reflective polarization layer, the polarizing layer WGP may reflect emitted light. For example, the first emitted light EL1 may be reflected from the polarizing layer WGP. Accordingly, the first emitted light EL1 and the first reflected light RL1 may be emitted from the first pixel PX1. The third emitted light EL3 and the third reflected light RL3 may be emitted from the third pixel PX3.

The micro lens array MLA may be disposed on the polarizing layer WGP. In an embodiment, the micro lens array MLA may include concave-shaped Fresnel lenses. For example, the micro lens array MLA may have a shape in which thin prism bands with a curvature corresponding to the curvature of the concave lens are divided and arranged based on a constant pitch. In other words, the micro lens array MLA may include a plurality of uneven patterns and a plurality of concave surfaces.

In an embodiment, the micro lens array MLA may include a first Fresnel lens FL1, a second Fresnel lens FL2, and a third Fresnel lens FL3. The first Fresnel lens FL1 may overlap the first pixel electrode PE1 and may correspond to the first pixel PX1. The second Fresnel lens FL2 may overlap the second pixel electrode PE2 and may correspond to the second pixel PX2. The third Fresnel lens FL3 may overlap the third pixel electrode PE3 and may correspond to the third pixel PX3.

In an embodiment, lens angles of the first to third Fresnel lenses FL1, FL2, and FL3 may increase from the center to the outside of the display panel PNL. For example, the lens angle of the first Fresnel lens FL1 may be greater than the lens angle of the second Fresnel lens FL2. In some aspects, the lens angle of the third Fresnel lens FL3 may be greater than the lens angle of the second Fresnel lens FL2.

Accordingly, the first Fresnel lens FL1 may refract the first emitted light EL1 and the first reflected light RL1 according to the first chief ray angle CRA1. The second Fresnel lens FL2 may refract the second emitted light EL2 according to the second chief ray angle CRA2. The third Fresnel lens FL3 may refract the third emitted light EL3 and the third reflected light RL3 according to the third chief ray angle CRA3.

Referring to FIGS. 6 and 7, the first pixel PX1 may emit light, and the light may include front light FRL1 and side light SL1. The front light FRL1 may have a relatively large amount of light compared to the side light SL1.

The front light FRL1 may travel in a vertical direction (e.g., the third direction D3) of the display panel PNL. Accordingly, the front light FRL1 reflected by the polarizing layer WGP may not travel to another adjacent color filter and the partition BM. In other words, the front light FRL1 reflected from the polarization layer WGP may be recycled as the first reflected light RL1.

The side light SL1 may proceed at a predetermined angle from the display panel PNL. Accordingly, the side light SL1 reflected from the polarizing layer WGP may travel to another adjacent color filter and/or the partition BM. In other words, the side light SL1 reflected by the polarizing layer WGP may not be recycled. For example, the side light SL1 reflected by the polarizing layer WGP may be filtered by an adjacent color filter and/or absorbed by the partition BM.

The first Fresnel lens FL1 may have a first lens angle LA1, and the first emitted light EL1 incident at the first lens angle LA1 may be refracted according to the first chief ray angle CRA1. In some aspects, the first reflected light RL1 incident at the first lens angle LA1 may be refracted according to the first chief ray angle CRA1.

As illustrated in FIG. 7, each of the Fresnel lenses may have a lens angle for refracting emitted light and reflected light according to the chief ray angle. In an example in which the refractive index of each Fresnel lens is 1.5 (n=1.5), the lens angles of the Fresnel lenses may increase from the center to the outside of the display panel PNL. In some aspects, each of the lens angles may be greater than the corresponding chief ray angle. For example, for a given Fresnel lens, the target chief ray angle may be about 20°, and the lens angle may be set to about 30°.

The display device DD may include the micro lens array MLA, and the micro lens array MLA may refract emitted light and reflected light according to a chief ray angle. For example, the micro lens array MLA may include first to third Fresnel lenses FL1, FL2, and FL3 corresponding to each of the first to third pixels PX1, PX2, and PX3. The lens angles of the first to third Fresnel lenses FL1, FL2, and FL3 may be set based on the first to third chief ray angles CRA1, CRA2, and CRA3 defined for each of the first to third pixels PX1, PX2, and PX3.

As the display device DD includes the micro lens array MLA, the front light (e.g., the first front light FRL1) having a relatively large light quantity and relatively high recycling efficiency may be refracted according to a chief ray angle (e.g., the first chief ray angle CRA1). Accordingly, light extraction efficiency for a pixel (e.g., the first pixel PX1) located outside of the display panel PNL may be improved.

In some aspects, as the display device DD includes the micro lens array MLA, the horizontal separation distance between the pixel electrode, the color filter, and the lens may not be shift aligned. For example, the horizontal separation distance (e.g., in the first direction D1) between the center of the first pixel electrode PE1 and the center of the first color filter CF1 may be equal to the horizontal separation distance (e.g., in the first direction D1) between the center of the second pixel electrode PE2 and the center of the second color filter CF2. Accordingly, the economic efficiency of the process of manufacturing the display device DD may be improved.

The planarization layer OC may be disposed on the micro lens array MLA. The planarization layer OC may include organic materials and/or inorganic materials. The planarization layer OC may compensate for steps caused by the polarization layer WGP and the micro lens array MLA.

The window WIN may be disposed on the planarization layer OC. The window WIN may include tempered glass, reinforced plastic, or the like. In an embodiment, the window WIN may be formed of a single layer or may have a structure in which a plurality of functional layers are stacked.

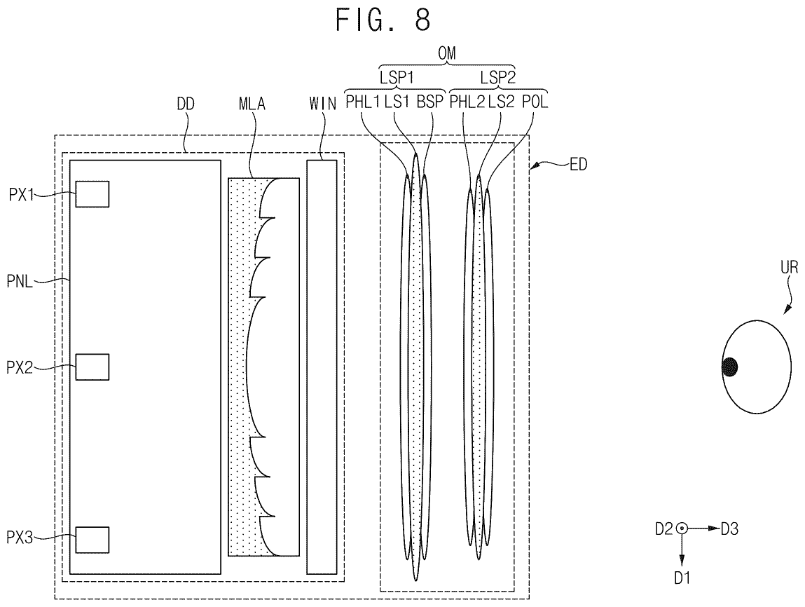

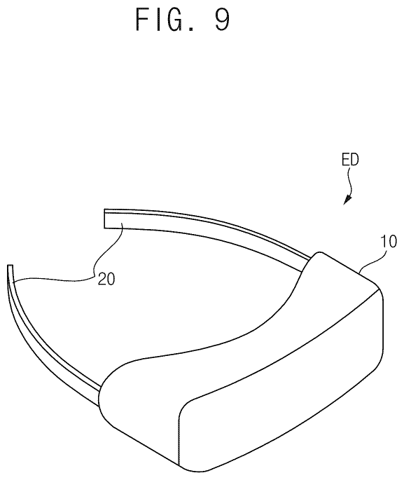

FIG. 8 is a diagram illustrating the electrical device of FIG. 1. FIG. 9 is a perspective view illustrating the electrical device of FIG. 1.

Referring to FIG. 8, the electrical device ED may include the display device DD and the optical member OM. The optical member OM may be disposed in a path of light emitted from the display device DD, may refract the light, and may provide the light to the user UR. The optical member OM may make the light emitted from the display device DD appear wider. For example, the optical member OM may widen or increase the diameter of the beam of the light emitted from the display device DD.

In an embodiment, the optical member OM may include a first lens part LSP1 and a second lens part LSP2. The first lens part LSP1 may include a first lens LS1, a first phase retardation layer PHL1, and a beam splitter BSP. The second lens part LSP2 may include a second lens LS2, a second phase retardation layer PHL2, and a polarizing plate POL.

The first lens LS1 and the second lens LS2 may be curved lenses. The curved surfaces of the first lens LS1 and the second lens LS2 may be spherical or aspherical. For example, each of the first lens LS1 and the second lens LS2 may include glass or polymethyl methacrylate (PMMA).

The first phase retardation layer PHL1 may be disposed on one side of the first lens LS1. For example, the first phase retardation layer PHL1 may be disposed on a side of the first lens LS1 which is adjacent to the display panel PNL. Expressed another way, the first phase retardation layer PHL1 may be disposed on a side of the first lens LS1 which is relatively closer to the display panel PNL. The first phase retardation layer PHL1 may have a retardation axis and may provide a phase difference with respect to the retardation axis. For example, the first phase retardation layer PHL1 may provide a phase difference of λ/4 or 3λ/4. Accordingly, the first phase retardation layer PHL1 may delay light in the retardation axis direction by λ/4 or 3λ/4 to convert linearly polarized light into circularly polarized light or convert circularly polarized light into linearly polarized light.

The beam splitter BSP may be placed on one side of the first lens LS1. For example, the beam splitter BSP may be disposed on a side of the first lens LS1 which is adjacent to the user UR. Expressed another way, the beam splitter BSP may be disposed on a side of the first lens LS1 which is relatively closer to the user UR. The beam splitter BSP may transmit a portion of the incident light and reflect other portions of the incident light. The beam splitter BSP may reflect and transmit light regardless of the polarization characteristics of the light. In an embodiment, the beam splitter BSP may include a translucent metal material.

The second phase retardation layer PHL2 may be disposed on one side of the second lens LS2. For example, the second phase retardation layer PHL2 may be disposed on a side of the second lens LS2 which is adjacent to the first lens part LSP1. Expressed another way, the second phase retardation layer PHL2 may be disposed on a side of the second lens LS2 which is relatively closer to the first lens part LSP1. The second phase retardation layer PHL2 may have a retardation axis and may provide a phase difference with respect to the retardation axis. For example, the second phase retardation layer PHL2 may provide a phase difference of λ/4 or 3λ/4. Accordingly, the second phase retardation layer PHL2 may delay light in the retardation axis direction by λ/4 or 3λ/4 to convert linearly polarized light into circularly polarized light or convert circularly polarized light into linearly polarized light.

The polarizing plate POL may be disposed on one side of the second lens LS2. For example, the polarizer POL may be disposed on a side of the second lens LS2 which is adjacent to the user UR. Expressed another way, the polarizer POL may be disposed on a side of the second lens LS2 which is relatively closer to the user UR.

In an embodiment, the polarizing plate POL may be a reflective polarizer. In this case, the polarizing plate POL may have a reflection axis. That is, the polarizing plate POL may reflect linearly polarized light which is traveling in the same direction as the reflection axis. That is, linearly polarized light which is traveling in the same direction as the reflection axis may not transmit through the polarizing plate POL. In some aspects, the polarizing plate POL may transmit linearly polarized light perpendicular to the reflection axis. That is, the polarizing plate POL may have a transmission axis perpendicular to the reflection axis.

Referring to FIG. 9, the electrical device ED may include a storage part 10 and eyeglass frame legs 20. For example, the electrical device ED may be implemented as a head mounted display. Hereinafter, the electrical device ED will be described as an example of the head mounted display.

The electrical device ED including the display device DD and the optical member OM may be accommodated in the storage part 10.

The electrical device ED may provide an image displayed on the display device DD stored in the storage part 10 to the user through an eyepiece or the like. Accordingly, the electrical device ED may provide a virtual image to the user. That is, the electrical device ED may implement virtual reality (VR).

The eyeglass frame legs 20 may be of a configuration which enables the user to easily put on or take off the electrical device ED. However, embodiments of the present disclosure are not necessarily limited thereto, and the electrical device ED may include a head-mounted band that can be worn on the head.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel in which a plurality of pixels are arranged side by side;
a micro lens array disposed on the display panel and configured to refract light emitted from each of the pixels according to a chief ray angle defined for each of the pixels; and
a window disposed on the micro lens array.

2. The display device of claim 1, wherein the micro lens array comprises Fresnel lenses disposed on the pixels.

3. The display device of claim 2, wherein each of the Fresnel lenses has a concave shape.

4. The display device of claim 2, wherein lens angles of the Fresnel lenses increase from a center to an outside of the display panel.

5. The display device of claim 4, wherein each of the lens angles is greater than a corresponding chief ray angle.

6. The display device of claim 1, wherein chief ray angles of the pixels increase from a center to an outside of the display panel.

7. The display device of claim 1, wherein the micro lens array is configured to refract the emitted light and reflected light associated with the emitted light according to the chief ray angle.

8. The display device of claim 7, further comprising:
a polarizing layer disposed between the display panel and the micro lens array and configured to reflect the emitted light.

9. The display device of claim 8, wherein the polarizing layer is a wire grid polarizing layer comprising grid patterns.

10. The display device of claim 1, further comprising:
a phase retardation layer disposed between the display panel and the micro lens array and configured to delay a phase of the emitted light.

11. The display device of claim 1, wherein:
each of the pixels comprises a pixel electrode and a color filter disposed on the pixel electrode, and
a horizontal separation distance between a center of a pixel electrode comprised in a first pixel for which a first chief ray angle is defined and a center of a color filter comprised in the first pixel is substantially equal to a horizontal separation distance between a center of a pixel electrode comprised in a second pixel for which a second chief ray angle, which is smaller than the first chief ray angle, is defined and a center of a color filter comprised in the second pixel.

12. The display device of claim 11, wherein the first pixel is located closer to an outside of the display panel than the second pixel.

13. The display device of claim 1, wherein each of the pixels comprises an intermediate layer in which at least two emission layers are stacked.

14. The display device of claim 13, wherein the intermediate layer emits white light.

15. The display device of claim 1, wherein:
the display panel comprises a substrate, and
the substrate is a silicon wafer comprising silicon or a sapphire substrate comprising sapphire.

16. The display device of claim 1, further comprising:
a planarization layer disposed between the micro lens array and the window.

17. An electrical device comprising:
a display device; and
an optical member disposed in a path of light emitted from the display device and comprising at least one lens part,
wherein the display device comprises:
a display panel in which a plurality of pixels are arranged side by side;
a micro lens array disposed on the display panel and configured to refract light emitted from each of the pixels according to a chief ray angle defined for each of the pixels; and
a window disposed on the micro lens array.

18. The electrical device of claim 17, wherein the lens part comprises a lens and a phase retardation layer disposed adjacent to the lens.
